(19) United States
(12) Patent Application Publication
(10) Pub. No.: US 2013/0292774 A1
(43) Pub. Date: Nov. 7, 2013

(54) METHOD FOR FORMING A SEMICONDUCTOR DEVICE HAVING RAISED DRAIN AND SOURCE REGIONS AND CORRESPONDING SEMICONDUCTOR DEVICE

(71) Applicants: Jan Hoentschel, Dresden (DE); Sven Beyer, Dresden (DE); Oliver Kallensee, Freital (DE); Stefan Flachowsky, Dresden (DE)

(72) Inventors: Jan Hoentschel, Dresden (DE); Sven Beyer, Dresden (DE); Oliver Kallensee, Freital (DE); Stefan Flachowsky, Dresden (DE)

(73) Assignee: GLOBALFOUNDRIES INC., Grand Cayman (KY)

(21) Appl. No.: 13/465,731

(22) Filed: May 7, 2012

(51) Int. Cl. H01L 27/088; H01L 21/336

(52) U.S. Cl. 257/368; 438/299; 257/E21.409; 257/E27.06

(57) ABSTRACT

A semiconductor device having raised source and drain regions is formed by forming a gate electrode structure on a semiconductor substrate, forming a first spacer structure laterally to the gate electrode structure, forming a semiconductor layer over an exposed surface of the semiconductor substrate at both sides of the gate electrode structure such that a layer portion is formed which is beveled towards the gate electrode with regard to the exposed surface of the semiconductor substrate, and forming a second spacer structure over the first spacer structure, wherein the second spacer structure covers at least a portion of the beveled layer portion.

### BACKGROUND OF THE INVENTION

1. Field of the Invention

The present invention generally relates to methods for forming semiconductor devices and to respective semiconductor devices and, more particularly, to the formation of semiconductor devices having raised source and drain regions and to respective semiconductor devices.

2. Description of the Related Art

Semiconductor devices conventionally comprise a large number of individual circuit elements, such as transistors, capacitors and resistors. These elements are internally connected to form complex integrated circuits which represent core elements of, for instance, memory devices, logic devices and microprocessors. In order to improve the performance of integrated circuits and, therefore, of semiconductor devices, recent efforts have been made to increase the number of functional elements in circuits and semiconductor devices in order to increase their functionality and/or by increasing the speed of operation of circuit elements and/or by reducing the amount of power consumed by circuit elements and/or semiconductor devices. The formation of a greater number of circuit elements on the same area is possible when reducing the sizes of features, hence allowing an extension of functionalities of circuits and reducing signal propagation delays resulting in increased speeds of operation of circuit elements. Therefore, a scaling of dimensions of semiconductor devices and/or circuit elements down to smaller scales and sizes opens possibilities for improving issues such as power consumption and speed of operation.

Field effect transistors represent a major component of integrated circuits and semiconductor devices. They are used as switching elements in integrated circuits and allow controlling a current which flows through a channel region located between a source region and a drain region. The source region and the drain region are both highly doped regions. In N-type transistors, the source and drain regions are doped with an N-type dopant, and conversely in P-type transistors, the source and drain regions are doped with a P-type dopant. The doping of the channel region is inverse to the doping of the source and drain region. A gate electrode formed above the channel region and which is separated from it by a thin insulating layer controls the conductivity of the channel region by an applied gate voltage. In dependence of the gate voltage, the channel region may be switched between a conductive state (“on state”) and a substantially non-conductive state (“off state”).

When reducing the size of field effect transistors, it is important to maintain a high conductivity of the channel region when the transistor is in the conductive or on state. The conductivity of the channel region in the on state depends on the dopant concentration of the channel region, the mobility of the charge carriers, the extension of the channel region in the width direction of the transistor and the distance between the source region and the drain region (which is commonly denoted as “channel length”). While a reduction of the width of the channel region leads to a decrease of the channel conductivity, a reduction of the channel length enhances the channel conductivity. An increase of the charge carrier mobility leads to an increased channel conductivity.

As feature sizes are reduced, the extension of the channel region in the width direction is also reduced. A reduction of the channel length entails a plurality of issues associated therewith. First, advanced techniques of photolithography and etching have to be provided in order to reliably and reproducibly create transistors having a short channel length. Moreover, highly sophisticated dopant profiles, in the vertical direction as well as in the lateral direction, are required in the source and in the drain region in order to provide a low sheet and contact resistivity in combination with a desired general controllability. A further problem when reducing the size or scale of integrated circuit elements, i.e., of transistors, is that device components of transistors such as the gate length and the thickness of gate insulator layers are scaled down accordingly. Extremely scaled semiconductor devices having critical dimensions much below 65 nm suffer, in general, from several problems that detrimentally affect device performance. For example, for extremely scaled semiconductor devices, the gate insulator material begins to exhibit excessive leakage and, therefore, cannot reliably well provide a sufficient electrical isolation between the gate electrode and the underlying channel region. Therefore, alternative materials having dielectric constants greater than about 4 (referred to herein as high-k dielectrics) have been considered for use in advanced devices including advanced CMOS devices. Gate insulators made from high-k dielectrics can be made thicker than those made of SiO₂ without sacrificing capacity properties and thus offer the benefit of a significant reduction of leakage currents. Candidate materials include transitional metal oxides, silicates and oxynitrides, such as hafnium oxide, hafnium silicide and hafnium oxynitride.

However, it has been discovered that high-k dielectric material are destabilized during subsequent anneal processes which may be performed in order to activate previously implanted dopants and re-crystallize crystal damages caused by implantation. The destabilization of the high-k gate dielectric leads to uncontrolled changes in the transistor's parameters and properties which may negatively affect the performance of the transistor or may even lead to device failure.

Another major issue encountered when increasing the performance of semiconductor devices and reducing the power consumption of semiconductor devices is given by contact and/or serial resistances (series resistors), especially in CMOS devices. In technologies concerning low power semiconductor devices, a possible approach to reduce contact resistances is given by a so-called raised source/drain approach. According to this approach, raised source regions and raised drain regions are formed adjacent a gate electrode by selectively epitaxially growing a semiconductor material layer over a semiconductor substrate. Usually a subsequent formation of silicided regions in the raised source and drain regions is performed to improve contacting. However, during the formation of silicided contact areas, another problem occurs when a conductive short circuit is created between the gate and either source or drain due to not properly isolated source/drain regions and unintended formation of silicide between gate electrode and source/drain region. Conventionally, careful and complicated etching and cleaning procedures have to be performed such that raised source/drain regions are formed without detrimentally affecting the high-k dielectric gate material and avoiding its destabilization.

US Patent Publication 2007/0254441 discloses formation of raised source and drain regions abutting a spacer of a gate electrode and subsequent formation of a further sidewall spacer on the source and drain regions. However, a reliable encapsulation of the high-k material protecting it from destabilizing effect and a reliable protection of the gate electrode structure from various etch and cleaning steps cannot be provided and the formation of short circuits between the source and drain regions and the gate electrode due to diffusion of ions from the source and drain regions towards the gate electrode may considerably degrade device performance. As the raised source and drain regions abut the gate electrode, great parasitic capacitances are formed between raised source and drain regions and the gate electrode leading to degraded device performances.

US Patent Publication 2010/0219485 shows a transistor having a gate electrode and two spacers disposed on the gate electrode. Raised source and drain regions contacting the two spacers are formed and subsequently the exterior spacer is etched back and a stressor liner layer is deposited over the raised source and drain regions and the gate electrode. Prior to formation of the stressor liner, implantation and annealing processes are performed in order to form final junctions and silicide regions. However, a reliable protection of the gate electrode structure and a reliable topography of the silicided regions and deep source and drain regions is not provided, whereas an additional overall stressor liner layer is provided, increasing process complexity to a considerable level.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

According to one illustrative embodiment of the present disclosure, a method for forming a semiconductor device having raised source and drain regions is provided. According to the method, a gate electrode is formed on a semiconductor substrate and a first spacer structure which is disposed laterally to the gate electrode is formed. A semiconductor layer is formed over an exposed surface of the semiconductor substrate at both sides of the gate electrode such that a beveled layer portion is formed towards the gate electrode, and a second spacer structure is formed over the first spacer structure, wherein the second spacer structure covers at least a portion of the beveled layer portion.

According to another illustrative embodiment of the present disclosure, a semiconductor device is provided. The semiconductor device comprises a semiconductor substrate having a transistor region on an exposed surface of the semiconductor substrate. A gate electrode structure is formed in the transistor region of the semiconductor substrate and a first spacer structure is formed in the transistor region disposed laterally to the gate electrode structure, wherein the first spacer structure covers a portion of the transistor region of the semiconductor substrate. A raised source region and a raised drain region are formed in an undoped semiconductor layer which is deposited on the semiconductor substrate in the transistor region at both sides of the gate electrode structure, wherein each of the raised source and drain regions have a layer portion which is beveled towards the gate electrode structure with regard to the exposed surface of the semiconductor substrate. A second spacer structure is formed over the first spacer structure, wherein the second spacer structure covers at least the beveled layer portions of the raised source and drain regions.

### BRIEF DESCRIPTION OF THE DRAWINGS

The disclosure may be understood by reference to the following description taken in conjunction with the accompanying drawings, in which like reference numerals identify like elements, and in which:

FIGS. 1-6 are cross-sectional views for illustrating semiconductor devices and methods for forming semiconductor devices according to illustrative embodiments of the present disclosure.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

In embodiments of the present disclosure, a semiconductor device having raised source and drain regions is formed by forming a gate electrode on a semiconductor substrate and by forming a first spacer structure disposed laterally to the gate electrode. A semiconductor layer is formed over an exposed surface of the semiconductor substrate at both sides of the gate electrode such that a layer portion may be formed which is beveled towards the gate electrode with regard to the exposed surface of the semiconductor substrate. A second spacer structure is formed over the first spacer structure, wherein the second spacer structure covers at least a portion of the beveled layer portion. A solid and reliable encapsulation of the gate electrode may be formed at early processing when forming a semiconductor device. Furthermore, at early manufacturing stages of semiconductor devices, a reliable encapsulation and protection of a high-k dielectric material in a gate structure may be obtained which advantageously affect gate first processes.

According to further embodiments of the present disclosure, a semiconductor device is provided wherein the semiconductor device comprises a semiconductor substrate, a gate electrode structure, a first spacer structure, a raised source region and a raised drain region, and a second spacer structure. The semiconductor substrate may have a transistor region on an exposed surface of the semiconductor substrate. The gate electrode structure may be formed in the transistor region of the semiconductor substrate. The first spacer structure may be formed in the transistor region and may be disposed laterally to the gate electrode structure. Herein, the first spacer structure may cover a portion of the transistor region of the semiconductor substrate. The raised source region and the raised drain region may be formed in an undoped semiconductor layer which may be deposited on the semiconductor substrate in the transistor region at both sides of the gate electrode structure. Herein each of the raised source and drain regions have a layer portion which is beveled towards the gate electrode structure with regard to the exposed surface of the semiconductor substrate. The second spacer structure may be formed over the first spacer structure. The second spacer structure may cover at least the beveled layer portions of the raised source and drain regions. An according semiconductor device may show improved device performance due to its reliable encapsulation and protection of the gate electrodes structure at early process steps. According semiconductor devices are especially protected against etching and cleaning processes. According semiconductor devices may have reduced parasitic capacitances while enabling mobility enhancement of charge carriers. Therefore, device parameters are conserved and a reliable and controlled device performance is provided.

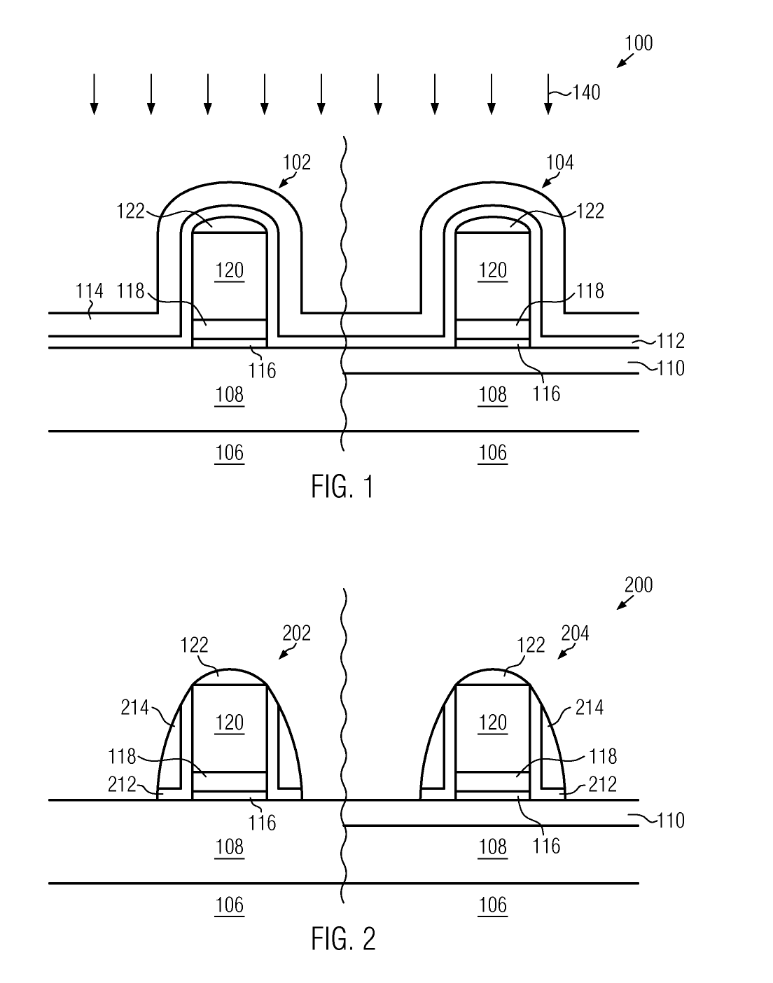

FIG. 1 shows a schematic cross-sectional view of a semiconductor device 100 at an early stage of a process for forming semiconductor devices according to an embodiment of the present disclosure. The semiconductor device 100 comprises a substrate 106 which may be formed on a buried insulator, such as an oxide layer (not shown), to give a semiconductor-on-insulator (SOI) configuration. Substrate 106 may also be provided by a bulk substrate. A layer of a semiconducting material 108 may be formed on the substrate 106 and shallow trench isolations (STI) (not shown) may be provided therein. Semiconductor device 100 as depicted in FIG. 1 may comprise an N-type semiconductor device denoted as 102 and a P-type semiconductor device 104. The N-type device 102 and the P-type device 104 may be disposed so as to form a CMOS configuration or may be disposed so as to not be in electrical contact with each other.

According to some exemplary embodiments, a gate electrode structure of N-type semiconductor device 102 and/or of P-type semiconductor device 104 may comprise a high-k dielectric layer 116, a work function adjusting layer 118, a polysilicon layer 120 and a cap layer 122. According to further exemplary embodiments, cap layer 122 may comprise a silicon oxide material and may have a thickness in a range from 10-100 nm or in a range from 20-50 nm or in a range from 25-45 nm.

The high-k material layer 116 may comprise a transitional metal oxide, such as at least one of hafnium oxide, hafnium dioxide and hafnium silicon-oxynitride. According to some exemplary embodiments, the high-k material layer 116 may be formed on the semiconductor layer 108. According to other embodiments, the high-k material layer 116 may be formed on an insulating layer (not shown) comprising silicon oxide which is formed on the semiconductor layer 108.

According to some exemplary embodiments, the work function adjusting layer 118 may comprise titanium nitride (TiN) or any other appropriate work function adjusting metal or metal oxide that is known in the art.

On the side of the P-type semiconductor device 104, semiconductor layer 108 may have a selective silicon/germanium channel 110. According to some embodiments, the channel 110 may have a thickness of less than 20 nm and more than 1 nm or a thickness of less than 10 nm and more than 5 nm. In some exemplary embodiments, the thickness of the silicon/germanium channel 110 may be approximately 8 nm. The person skilled in the art understands that the thickness of the silicon/germanium channel 110 may be formed in accordance with some exemplary embodiments to have an averaged thickness of 8 nm and may have thickness values which vary in a range of more or less than 3 nm around the averaged value of 8 nm. The averaged thickness may be determined in accordance with an illustrative technique by choosing a grid pattern structure corresponding to a desired exactness, wherein measurement points for determining thickness values of a layer are aligned with regard to vertices of the grid pattern, and measuring the thickness of the layer at the measurement points which correspond to vertices of the grid pattern structure. In using known averaging techniques, an averaged value may thus be obtained. The person skilled in the art understands that many different methods and techniques are possible in order to determine an averaged thickness of a layer and, accordingly, the foregoing explained technique is only given for illustrative purposes and is not intended to limit the scope of the present disclosure. The selective silicon/germanium channel 110 may be provided to adjust the threshold voltage of the P-type semiconductor device 104 in order to match the threshold voltage of P-type semiconductor device 104 with the threshold voltage of the N-type semiconductor device 102.

A first insulating layer 112 and a second insulating layer 114 may be formed over the gate electrode structure and the substrate. The first and second insulating layers 112, 114 may be formed by, for instance, epitaxially growing or depositing respective layers. According to some exemplary embodiments, the first and/or the second insulating layers 112, 114 may be substantially uniformly formed over the semiconductor layer 108 and/or at least one gate electrode structure.

According to some exemplary embodiments, the first insulating layer 112 may be comprised of silicon nitride (SiN). According to some exemplary embodiments, the first insulating layer 112 may have a thickness of substantially less than 10 nm or may have a thickness of substantially less than 5 nm or may have a thickness of substantially less than 1 nm or may substantially be a monolayer having a thickness of less than 1 nm.

According to some exemplary embodiments, the second insulating layer 114 may comprise silicon dioxide (SiO₂) and may have a thickness which is substantially greater than the thickness of the first insulating layer 112. According to some exemplary embodiments, the second insulating layer 114 may have a thickness which is substantially greater than 1 nm or which is substantially greater than 5 nm or which is substantially greater than 10 nm.

According to some exemplary embodiments, the silicon/germanium channel 110 may have a content of silicon/germanium between approximately 10-50% or between approximately 15-40% or between approximately 19-30%. The content of silicon/germanium in the selective silicon/germanium channel may vary in accordance with one of the aforementioned ranges.

According to an appropriate etching, the deposited layers 112 and 114 may be etched to form a spacer structure which is represented in FIG. 1 by an etching step 140. Etching step 140 as schematically depicted in FIG. 1 for ease of illustration may represent one etch step or may alternatively comprise two or more etching steps and, therefore, represent an etching process comprising two or more etching steps.

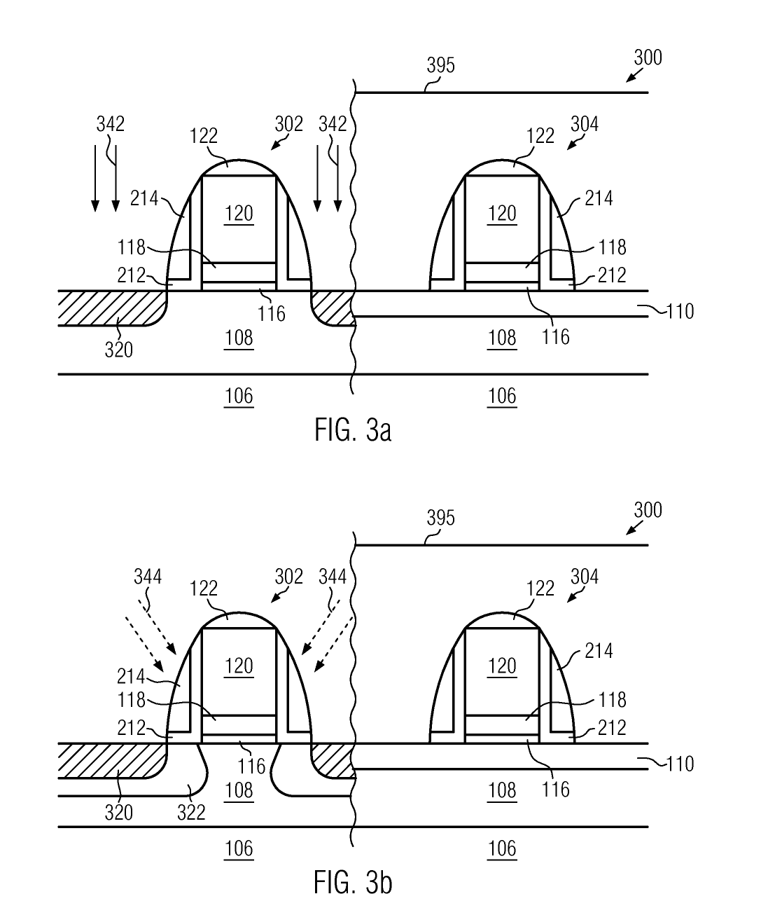

FIG. 2 shows a schematic cross-sectional view of a semiconductor device 200 which may be obtained by processing semiconductor device 100 as explained with regard to FIG. 1. The person skilled in the art understands that this poses no limitation on the semiconductor device 200 and also different processing steps possibly resulting in semiconductor device 200 may be considered.

Semiconductor device 200 as depicted in FIG. 2 comprises an N-type semiconductor device 202 and a P-type semiconductor device 204 which may be in electrical contact to form a CMOS structure or may be disposed on the semiconductor substrate 106 so as to be not in electrical contact with each other. As depicted in FIG. 2, a first spacer structure is formed laterally disposed with regard to a gate electrode structure of an N-type semiconductor device 202, and a first spacer structure is formed laterally disposed with regard to a gate electrode structure of a P-type semiconductor device 204.

The first spacer structure has a first spacer liner 212 and a first sidewall spacer 214, thus forming a sidewall spacer structure. According to some exemplary embodiments, the first spacer liner 212 may have a substantially L-type shape. The person skilled in the art understands that the first spacer liner 212 according to some exemplary embodiments of the present disclosure may cover at least a portion of a sidewall surface of the gate electrode structure of N-type semiconductor device 202 and/or P-type semiconductor device 204. The person skilled in the art understands that the first spacer liner 212 may additionally or alternatively cover a portion of the semiconductor layer 108 in a region adjacent the gate electrode structure of N-type semiconductor device 202 and/or of P-type semiconductor device 204. The first sidewall spacer 214 may be disposed over the first spacer liner 212. According to some exemplary embodiments, the first sidewall spacer 214 may be disposed so as to at least partially cover the first spacer liner 212. The person skilled in the art understands that at least one of the gate electrode structure of N-type semiconductor device 202 and the gate electrode structure of P-type semiconductor device 204 may be encapsulated due to the first sidewall spacer structure 212, 214 and the cap layer 122 as shown in FIG. 2. Therefore, at an early processing stage, a gate electrode structure of at least one of the N-type semiconductor device 202 and the P-type semiconductor device 204 may be reliably and stably encapsulated by the first spacer structure, thus corresponding to a solid spacer structure. The person skilled in the art understands that the gate electrode structure and, in particular, the high-k dielectric layer 116 may be reliably and stably protected during etching and cleaning steps which are to be subsequently performed.

The person skilled in the art understands that according to some exemplary embodiments, the first spacer structure may comprise at least the first spacer liner 212 and the first sidewall spacer 214. According to further exemplary embodiments herein, the first spacer structure may further comprise the cap layer 122.

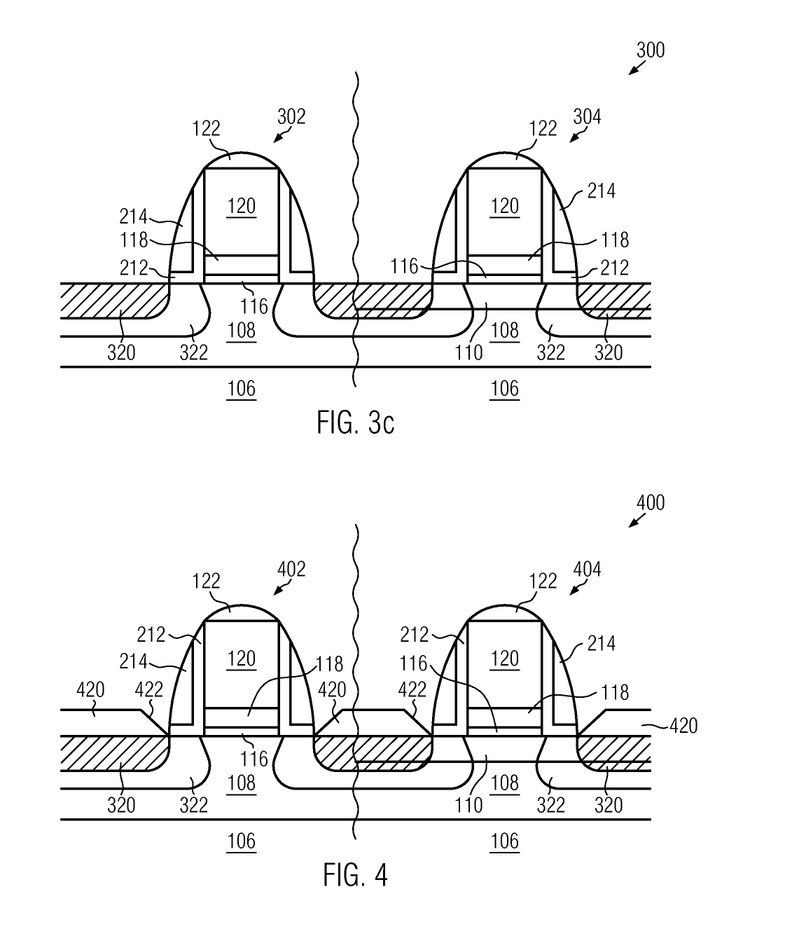

FIG. 3a shows a semiconductor device 300 during a stage in a formation process for forming a semiconductor device having raised source and drain regions. The semiconductor device 300 may be obtained subsequent to processing steps as explained with regard to FIGS. 1 and 2. However, this does not pose any limitation on semiconductor device 300 and the person skilled in the art will understand that semiconductor device 300 may be possibly obtained by different processing steps.

Semiconductor device 300 has a first spacer structure 214, 212 disposed laterally to a gate electrode structure of an N-type semiconductor device 302 and/or a P-type semiconductor device 304. P-type semiconductor device 302 and N-type semiconductor device 304 may be disposed to form a CMOS structure or may not be in electrical contact with each other. As schematically depicted in FIG. 3a, a mask or hard mask 395 may be disposed over P-type semiconductor device 304 in order to protect P-type semiconductor device 304 from subsequent processing steps. According to some exemplary embodiments, the mask or hard mask 395 may be based on a photoresist and may be formed in accordance with corresponding deposition steps. It is understood that the mask or hard mask 395 is only schematically shown and does not pose any limitations on the scope of the present disclosure. Due to mask or hard mask 395, N-type semiconductor device 302 is exposed to processing steps at this stage and P-type semiconductor device 304 is not exposed to the processing steps at this stage.

FIG. 3a schematically depicts an implantation step 342 during which source and drain extension regions 320 may be formed in the semiconductor layer 108. The person skilled in the art will appreciate that the first spacer structure 212, 214 may represent a first masking pattern for the implantation of source/drain extension regions 320. The source/drain extension regions 320 may be aligned with regard to the first spacer structure. The first spacer structure 212, 214 may set the distance of the source/drain extension regions 320. The person skilled in the art understands that the first spacer structure may reliably encapsulate and protect the gate electrode structure of the N-type semiconductor device 302 during early processing steps. The cap layer 122 protects the gate electrode structure of N-type semiconductor device 302 from being affected by implantation step 342.

Although FIG. 3a schematically depicts extension regions 320 that do not reach under the first spacer structure, the person skilled in the art understands that, due to scattering processes, ions may be laterally scattered by atoms of semiconductor layer 108 such that ions may also be implanted into a region disposed under the first spacer structure 212, 214 of N-type semiconductor device 302 and, therefore, it is understood that source/drain extension regions 320 may possibly extend under the first spacer structure 212, 214. The person skilled in the art understands that the source/drain extension regions 320 may be aligned with regard to the gate electrode structure due to the first spacer structure 212, 214 of N-type semiconductor device 302 by taking the aforementioned scattering processes into account.

FIG. 3b shows semiconductor device 300 when N-type semiconductor device 302 is exposed to a subsequent halo implantation step 344 by which halo regions 322 may be formed in semiconductor layer 108 at the side of the N-type semiconductor device 302. The halo implantation step 344 may be performed under an inclined angle with regard to the exposed surface of the semiconductor layer 108, i.e., an angle under which the halo implantation step is performed with regard to the exposed surface of the semiconductor layer 108 is substantially different from a direction parallel to a normal direction of the exposed surface of the semiconductor layer 108. In this manner, the halo region 322 may be formed which substantially extends under the first spacer structure 212, 214. The spacer structure 212, 214 may reliably encapsulate and protect the gate electrode structure of N-type semiconductor device 302 while the shape of the halo region 322 is determined through the inclined implantation 344. The shape of the halo regions 322 may be affected by the first spacer structure 212, 214. At the same time, the P-type semiconductor device 304 is protected by the mask or hard mask 395 and, consequently, the P-type semiconductor device 304 is not exposed to the halo implantation 344.

Subsequent to the aforementioned implantation steps, the mask or hard mask 395 may be removed such that the P-type semiconductor device 304 may be exposed to corresponding implantation steps for accordingly forming source/drain extension regions and/or halo regions in the P-type semiconductor device 304. The person with ordinary skills in the art will understand that this does not pose any limitation on the disclosed process. It is also possible to first mask the N-type semiconductor device 302 and accordingly to expose the P-type semiconductor device 304 to implantation steps for accordingly forming source/drain extension regions 320 and/or halo regions 322 without exposing N-type semiconductor device 302 to said implantations and subsequently to mask the P-type semiconductor device 304 and to expose the N-type semiconductor device 302 to corresponding implantation steps for forming source/drain extension regions and/or halo regions without exposing P-type semiconductor device 304 to said implantations.

After applying source/drain extension region implantation steps and halo implantation steps to the N-type semiconductor device 302 and the P-type semiconductor device 304, source/drain extension regions 320 and halo regions 322 are formed in N-type semiconductor devices 302 and P-type semiconductor devices 304 as depicted in FIG. 3c. It is appreciated that the source/drain extension regions 320 and the halo regions 322 of P-type semiconductor device 304 are implanted to a depth into the semiconductor layer 108 which is substantially bigger than a depth of the selective silicon/germanium channel 110.

Although not shown in FIG. 3c, the person skilled in the art will understand that it is possible to embed stressor regions (not shown) into extended source/drain regions 320 of N-type semiconductor device 302 and/or P-type semiconductor device 304 for imparting stress on the channel region of N-type semiconductor device 302 and/or P-type semiconductor device 304 disposed under the gate electrode structure of N-type semiconductor device 302 and/or P-type semiconductor device 304. The person skilled in the art understands that by imparting stress on channel regions, the mobility of charge carriers in the channel region may be affected and especially improved. According to some exemplary embodiments, a silicon/germanium region (not shown) may be embedded in the semiconductor layer 108 at P-type semiconductor device 304 to a depth greater than the depth of the selective silicon/germanium channel 110 of the semiconductor device 304. The person skilled in the art appreciates that for forming stressor regions in P-type semiconductor device 304, the processing further comprises the steps of etching recesses into the semiconductor layer 108 of the P-type semiconductor device 304 adjacent the first spacer structure 212, 214 using a reactive ion-etch process which may comprise at least one of one or more isotropic etch steps and/or one or more anisotropic etch steps. A typical isotropic dry-etch process may be carried out in a plasma etching chamber using a gas chemistry comprising Cl₂, HF and/or SF₆ and process conditions that favor isotropic (or lateral) etch. In addition, the etch chemistry may be chosen such that it may be highly selective to the material surrounding the gate electrode structure of the P-type semiconductor device 304. In this way, the oxide and nitride spacers surrounding the gate electrode structures of P-type semiconductor device 304 may be not etched or may be etched to a minimum extent. The person skilled in the art understands that the first spacer structure 212, 214 may reliably encapsulate and protect the gate electrode structure of P-type semiconductor device 304 during these processes.

Subsequent to etch processes, an epitaxial pre-cleaning of the recessed surface may be performed. The epitaxial pre-cleaning may preferably comprise HF either in gaseous or liquid state or a combination of steps and chemicals which include gaseous HF or liquid HF. The person with skills in the art appreciates that the first spacer structure 212, 214 reliably encapsulates and protects the gate electrode structure of P-type semiconductor device 304 when exposed to pre-cleaning. In the recessed source/drain regions, a silicon/germanium alloy forming a lattice mismatched region adjacent the channel of P-type semiconductor device 304 may be formed to cause strain imparted in the general direction. The person with skills in the art appreciates that the lattice mismatched region may be formed using an epitaxial growth process such as chemical vapor deposition (CVD), ultra-high vacuum chemical vapor deposition or molecular beam epitaxy. The epitaxy process may be selective because silicon/germanium only grows on exposed silicon regions and not on the oxide or nitride protected gate electrode structure. It is understood that the lattice mismatched regions may be aligned with respect to the first spacer structure 212, 214 and the cap layer 122. The person with ordinary skills in the art understands that the spacer structure may be accordingly used as a first masking pattern for aligning the lattice mismatched regions or stressor regions or stress-inducing regions with the gate electrode structure of the P-type semiconductor device 304. The silicon/germanium stressor may be in situ doped with boron. The germanium concentration in the silicon/germanium alloy may be between approximately 10-40 atomic percent. A possible boron concentration in the silicon/germanium alloy may be between approximately 8E19/cm³−1E21/cm³. The person skilled in the art will understand that according to alternative exemplary embodiments herein, undoped silicon/germanium may be first grown followed by an ion implantation and an anneal step before activating the dopants (e.g., boron). The person with skills in the art will understand that the gate electrode structure of the P-type semiconductor device 304 is reliably encapsulated and protected by the first spacer structure 212, 214. It is further understood that during the aforementioned process of including lattice mismatch regions or stressor regions or stress-inducing regions into the P-type semiconductor device 304, the N-type semiconductor device 302 may be protected by appropriate masks or hard masks, as it is, for example, explained with regard to mask or hard mask 395. It is further noted that lattice mismatched regions or stressor regions or stress-inducing regions may be accordingly provided for the N-type semiconductor device 302, as it is known in the art. In accordance to the aforementioned provision of lattice mismatched regions or stressor regions or stress-inducing regions in P-type semiconductor device 304, lattice mismatched regions or stressor regions or stress-inducing regions may be provided in N-type semiconductor device 302. The person skilled in the art understands that the mobility of electrons may be enhanced due to lattice mismatched regions or stressor regions or stress-inducing regions comprising at least one of indium (In), gallium (Ga) and arsenic (As).

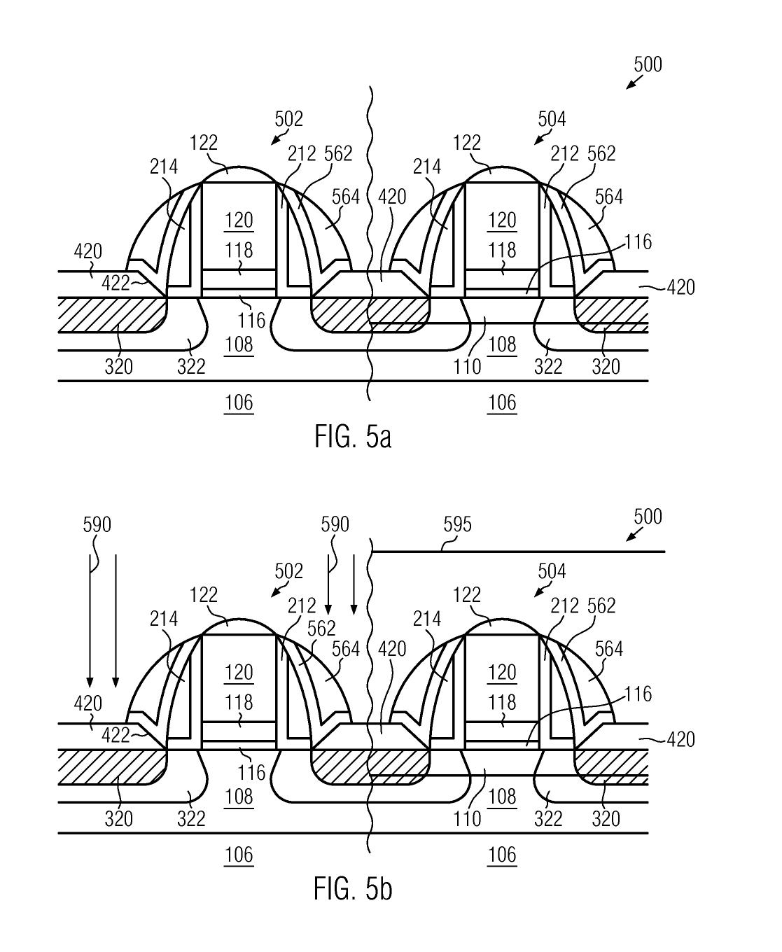

FIG. 4 shows a semiconductor device 400 during a stage in a formation process for forming a semiconductor device having raised source and drain regions. The semiconductor device 400 may be obtained subsequent to processing steps as explained with regard to FIGS. 1, 2 and 3a-3c. However, this does not pose any limitation on semiconductor device 400 and the person skilled in the art will understand that semiconductor device 400 may be possibly obtained by processing steps different from the aforementioned.

Semiconductor device 400 may comprise an N-type semiconductor device 402 and a P-type semiconductor device 404. The N-type semiconductor device 402 and the P-type semiconductor device 404 may be in electrical contact to form a CMOS semiconductor device or may be disposed on the semiconductor substrate 106 so as to not be in electrical contact. FIG. 4 depicts the semiconductor device 400 in a process step where a semiconductor layer 420 is formed over an exposed surface of the semiconductor layer 108 at both sides of the gate electrode. The semiconductor layer 420 may be formed over the source/drain extension regions 320. According to some exemplary embodiments, the semiconductor layer 420 may comprise silicon. According to further exemplary embodiments herein, the semiconductor layer 420 may comprise undoped silicon.

According to some exemplary embodiments, the formation of semiconductor layer 420 may be performed by epitaxial growing or selective epitaxial growing or by depositing a semiconductor material which is to form a semiconductor layer 420 over exposed surfaces of semiconductor layer 108 of N-type semiconductor device 402 and/or P-type semiconductor device 404. The thickness of the semiconductor layer 420 may be in a range between approximately 20-40 nm. The thickness of the semiconductor layer 420 may vary between the aforementioned ranges. The person with ordinary skills in the art understands that the formation of the semiconductor layer 420 provides a further encapsulation of the gate electrode structure of the N-type semiconductor device 402 and/or P-type semiconductor device 404. The person with ordinary skills in the art appreciates that at least the first spacer structure may be used as a first masking pattern when depositing semiconductor layer 420 while reliably encapsulating and protecting the gate electrode structure of the N-type semiconductor device 402 and the P-type semiconductor device 404 and maintaining the first spacer structure 212, 214 and the cap layer 122.

According to some exemplary embodiments, the semiconductor layer 420 may be formed over the exposed surface of the semiconductor substrate at both sides of the gate electrode such that a layer portion 422 which is beveled towards the gate electrode structure of the N-type semiconductor device 402 and the P-type semiconductor device 404 with regard to the exposed surface of the semiconductor layer 108 is at least partially covered by the semiconductor layer 420. The person skilled in the art understands that the beveled layer portion 422 of semiconductor layer 420 reduces possible parasitic capacitances which may arise due to portions of raised source/drain regions which are disposed adjacent gate electrode structures. For forming the beveled layer portion 422, an epitaxy technique may be performed which makes use of the effect that the speed of epitaxial growth depends on the orientation of the crystal surface on which material is to be grown. The person skilled in the art appreciates that growth of silicon on a (111) surface is substantially suppressed. However, this does not pose any limitation on the present disclosure, and other techniques may be considered for forming beveled layer portions 422.

The semiconductor device depicted in FIG. 4 may be exposed to a pre-clean process. According to some exemplary embodiments, the pre-clean process may be adapted to the thickness of the cap layer 122 and the thickness of the first sidewall spacer 214 such that the pre-clean process does not substantially alter the thickness of the cap layer 122 and/or the thickness of the first sidewall spacer 214. In this regard, the pre-clean process may be understood as being optimized. By not altering the thickness of the cap layer 122 and/or the thickness of the first sidewall spacer 214, it is meant that the original thickness of the cap layer 122 and/or the thickness of the first sidewall spacer 214 formed during the formation process of cap layer 122 and/or the first sidewall spacer 214 is substantially equal to a thickness of cap layer 122 and/or a thickness of the first sidewall spacer 214 after the pre-clean process is performed. According to some exemplary embodiments, thicknesses of sidewall spacers and cap layers may not deviate by more than 50% or more than 25% or more than 10% or more than 5% or more than 1% or more than 0.5%. According to some exemplary embodiments, the pre-clean process may comprise usage of HF. According to some exemplary embodiments, the pre-clean process may be time controlled so as to not substantially affect the thickness of the cap layer 122. According to some exemplary embodiments, the pre-clean process may make use of an optimized HF chemistry mixture, e.g., diluted HF, such that the cap layer 122 is substantially not reduced in thickness.

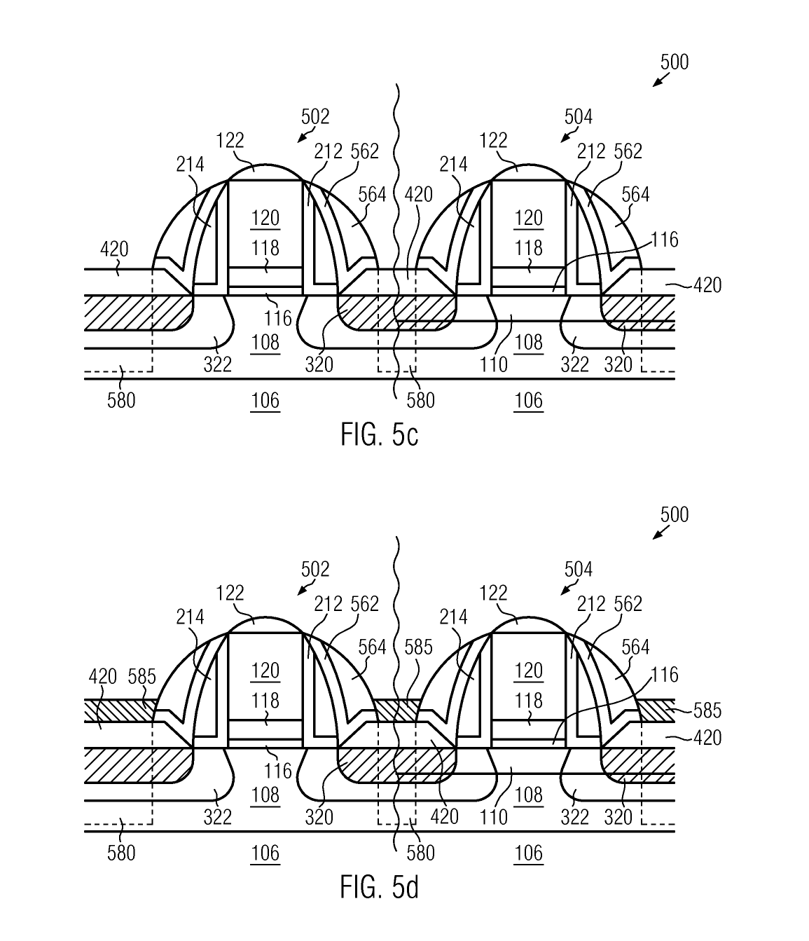

FIG. 5a shows a semiconductor device 500 during a stage in a formation process for forming a semiconductor device having raised source and drain regions. The semiconductor device 500 may be obtained subsequent to processing steps as explained with regard to FIG. 1, 2, 3a-3c and 4. However, this does not pose any limitation on semiconductor device 500 and the person skilled in the art will understand that semiconductor device 500 may possibly be obtained by processing steps different from the aforementioned.

FIG. 5a depicts a semiconductor device 500 comprising an N-type semiconductor device 502 and a P-type semiconductor device 504 which may be provided for forming a CMOS structure or which may be disposed over the semiconductor substrate 106 such that N-type semiconductor device 502 and P-type semiconductor device 504 are not in electrical contact. FIG. 5a shows the semiconductor device 500 after a formation process for forming a second spacer structure having a second spacer liner 562 and a second sidewall spacer 564. The second spacer structure 562, 564 may be obtained by a similar process as explained with regard to FIG. 1 in the context of the formation of the first spacer structure 212, 214. However, the person with ordinary skills in the art will understand that this does not pose any limitation to the formation of the second spacer structure 562, 564. It is also possible that the second spacer structure is formed by a selective deposition process and/or a suitable masking process followed by a subsequent deposition process and subsequent etching and cleaning steps and/or by first depositing the second spacer liner 562 followed by an etching step and subsequent deposition of the second sidewall spacer 564 followed by a subsequent etching step. According to some exemplary embodiments, the cap layer 122 is disposed over the gate electrode structure of the N-type semiconductor device 502 and/or the P-type semiconductor device 504.

The second spacer structure 562, 564 may be formed over the first spacer structure 212, 214. According to some exemplary embodiments, the second spacer structure 562, 564 is formed over the semiconductor layer 420 such that at least a portion of the beveled layer portion 422 is covered. The second spacer liner 562 may have a substantially L-type shape. The person skilled in the art understands that the second spacer liner 562 may be formed at least over the first sidewall spacer 214 so as to cover the first sidewall spacer 214. According to some exemplary embodiments, the second sidewall spacer 564 may formed over at least a portion of the second spacer liner 562 so as to at least partially cover the second spacer liner 562. The person skilled in the art understands that the second spacer structure 562, 564 is formed over at least a portion of the first spacer structure 212, 214 and/or the gate electrode structure so as to at least partially cover the first spacer structure 212, 214 and/or to at least partially cover the gate electrode structure. The second spacer liner 562 may have a thickness which is substantially thinner than a thickness of the second sidewall spacer 564.

According to some exemplary embodiments, the second spacer liner 562 may comprise silicon dioxide and/or the second sidewall spacer 564 may comprise silicon nitride. The person with ordinary skills in the art will appreciate that the second sidewall spacer structure 562, 564 provides reliable encapsulation and protection of the gate electrode structure of the N-type semiconductor device 502 and/or the P-type semiconductor device 504.

FIG. 5b shows the semiconductor device 500 according to a subsequent processing step. The P-type semiconductor device 504 may be covered by a mask or hard mask 595 such that only the N-type semiconductor device 502 may be exposed to subsequent processing which is to be performed. The N-type semiconductor device 502 may be exposed to an ion implantation step 590 which is accordingly not applied to the P-type semiconductor device 504 due to the mask or hard mask 595.

It is appreciated that, according to an alternative embodiment, a mask or hard mask may be disposed over the N-type semiconductor device 502 such that an according implantation step 590 may be applied to the P-type semiconductor device 504 while not exposing the N-type semiconductor device 502 to the implantation. It is remarked that an ion implantation 590 applied to the N-type semiconductor device 502 may be followed by an according ion implantation of the P-type semiconductor device 504 or an ion implantation applied to the P-type semiconductor device 504 may be followed by an according ion implantation step 590 applied to the N-type semiconductor device 502. It is appreciated that between subsequent ion implantation steps applied to the N-type semiconductor device 502 or the P-type semiconductor device 504, cleaning and patterning steps may be applied to the P-type semiconductor device 504 or the N-type semiconductor device 504. It is noted that FIG. 5b does not intend to identify any preferred ordering, but that orderings that are explained with regard to FIG. 5b are only for illustrative purposes and not intended to limit the scope of the present disclosure.

FIG. 5c depicts the semiconductor device 500 after the aforementioned ion implantation steps forming deep source and drain regions 580 in the N-type semiconductor device 502 and/or the P-type semiconductor device 504. The deep source and drain regions 580 may be formed in semiconductor layer 420 and semiconductor layer 108 while the second spacer structure 562, 564 may be used as a second masking pattern. According to some exemplary embodiments, the deep source and drain regions 580 may be aligned with regard to the gate electrode structure of the N-type semiconductor device 502 and/or the P-type semiconductor device 504. The person skilled in the art understands that the second spacer structure 562, 564 may set the distance of the deep source/drain implantations. It is noted that, although the deep source and drain regions 580 are depicted in FIG. 5c so as to not extend under the second spacer structure 562, 564, it is possible that implanted species may be scattered in at least one of semiconductor layers 420 and 108 such that deep source and drain regions 580 may possibly have portions that at least partially extend under the second spacer structure 562, 564 or even under the first spacer structure 212, 214.

FIG. 5d shows the semiconductor device 500 after forming a metal layer 585 over the semiconductor layer 420 in the N-type semiconductor device 502 and/or the P-type semiconductor device 504. The person with skills in the art appreciates that the second spacer structure 562, 564 may be used as a second masking pattern when depositing the metal layer 585. The person skilled in the art further appreciates that the second spacer structure 562, 564 may align the deposited metal layer 585 with regard to the gate electrode structure of the N-type semiconductor device 502 and/or the P-type semiconductor device 504. According to some exemplary embodiments, the formation of the metal layer 585 may comprise epitaxial growing steps or other suitable depositing steps as known in the art.

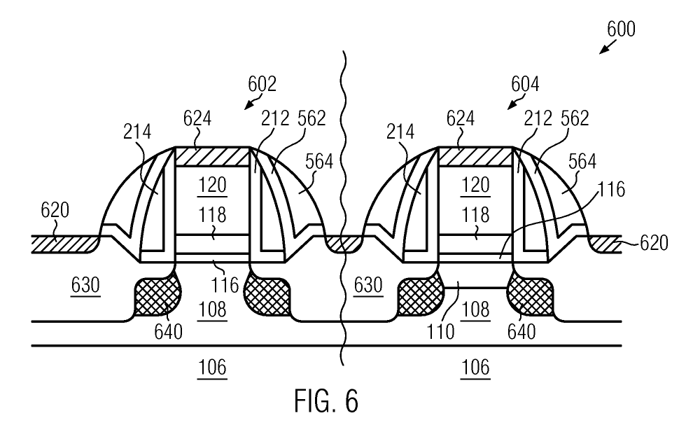

FIG. 6 shows a semiconductor device 600 during a stage in a formation process for forming a semiconductor device having raised source and drain regions. The semiconductor device 600 may be obtained subsequent to processing steps as explained with regard to FIG. 1, 2, 3a-3c, 4 and 5a-5c. However, this does not pose any limitation on semiconductor device 600 and the person skilled in the art will understand that the semiconductor device 600 may possibly be obtained by processing steps different from the aforementioned.

The semiconductor device 600 as schematically depicted in FIG. 6 may comprise an N-type semiconductor device 602 and a P-type semiconductor device 604. The N-type semiconductor device 602 and the P-type semiconductor device 604 may be disposed so as to possibly form a CMOS structure or may be disposed on the semiconductor substrate 106 without being in electrical contact.

According to some exemplary embodiments, the semiconductor device 600 depicted in FIG. 6 may be obtained from the semiconductor device 500 as shown in FIG. 5d after applying a pre-silicide cleaning step for opening the polysilicon layer 120 for silicidation by removing the cap layer 122 (FIG. 5d) from the gate structures. According to some exemplary embodiments, the pre-silicide cleaning step may comprise applying liquid and/or gaseous HF. The person skilled in the art appreciates that the gate electrode structures are reliably encapsulated and protected by the first spacer structure 212, 214 and the second spacer structure 562, 564 during the pre-silicide cleaning step applied to the semiconductor device 500 as depicted in FIG. 5d.

Subsequent to the pre-silicide cleaning step, the semiconductor device may be exposed to a silicidation step for forming silicide regions 620 as shown in FIG. 6. The person skilled in the art understands that the silicidation step may be performed by using the second spacer structure 562, 564 as a second masking pattern. Therefore, the person skilled in the art understands that the second spacer structure 562, 564 may set the distance of the silicided portions of the layer 420 (FIG. 5d), i.e., of the silicide regions 620, of the N-type semiconductor device 602 and the P-type semiconductor device 604.

The person skilled in the art understands that subsequent to the aforementioned pre-cleaning step, various processing steps may be performed to form a gate silicide region 624 on the gate stack of the N-type semiconductor device 602 and/or the P-type semiconductor device 604. It is noted that formation of gate silicide regions 624 may be performed at the time when forming silicided regions 620 or subsequent to forming silicided regions 620. The person skilled in the art understands that the silicided regions 620 are aligned with regard to the spacer structure.

Together with the silicidation step or subsequent to the silicidation step, the implanted dopants may be annealed for activating the dopants and curing damages in the silicon crystal, e.g., by re-crystallization. The person with ordinary skills in the art will appreciate that the first spacer structure 212, 214 and the second spacer structure 562, 564 reliably encapsulate and protect the gate electrode structure of the N-type semiconductor device 602 and the P-type semiconductor device 604 during the annealing and silicidation step or steps such that the high-k dielectric layer 116 is stabilized and, accordingly, the parameters of the N-type semiconductor device 602 and the P-type semiconductor device 604 are not altered.

As depicted in FIG. 6, the annealing and silicidation step or steps result in source and drain regions 630 defining channel regions for semiconductor devices 602 and 604 and having silicide contact regions 620 embedded in raised source and drain regions. According to some exemplary embodiments, halo pocket regions 640 may be formed, as depicted in FIG. 6. Although not shown in FIG. 6, the semiconductor device 600 may have stressor or stress-inducing regions embedded in the raised source/drain regions 630 for imparting stress on channel regions.

The raised source/drain regions 630 reduce contact sheet resistances and serial resistances (series resistors) resulting in an improved device performance. Additionally, the person skilled in the art will appreciate that, according to some exemplary embodiments, a very solid encapsulation, especially at the foot of the first spacer structure 212, 214, may take place and attacks from cleaning, stripping and/or rinsing steps may be avoided, or may occur at least in a reduced manner, leading to an increased yield. Furthermore, the person skilled in the art will appreciate that easier contact processes may take place because a sufficient amount of silicide may be provided. The person understands that, due to the first and second spacer structures, self-aligned formation processes for source/drain regions and/or raised source/drain regions and/or silicide regions and or stressor regions may be performed leading to simplified processing technologies. It is understood that provision of the cap layer and its maintenance until after self-aligned formation steps may reliably encapsulate and protect gate electrode structures and simplify known formation processes.

After having studied the present disclosure, the person skilled in the art will appreciate that methods as implied by the present disclosure help in reducing the number of processing steps and, therefore, provide an easy and uncomplicated process structure when manufacturing semiconductor devices. In forming the first spacer structure, the second spacer structure and a capping layer, the gate stack and especially the high-k material may be reliably and stably encapsulated and protected against being detrimentally affected by annealing, etching, cleaning, rinsing and/or stripping processes without adding more complex processing steps to existing solutions. Certain particular but not limiting embodiments provide for a formation of SiO₂—SiN—SiN—SiO₂ sidewall spacer structures and an SiO₂ capping layer over the gate electrode. The person skilled in the art understands that according structures and methods providing according structures considerably reduce process complexity in reducing the amount of processing steps for achieving a reliable and stable encapsulation of a gate electrode because the capping layer and the sidewall spacer structure may be formed so as to omit certain masking, patterning, structuring, processing, cleaning, rinsing, etching, stripping and/or annealing steps.

The person skilled in the art understands that optimized pre-cleaning steps may be performed during the processing which may not substantially affect the capping layer. Exemplary optimized cleaning steps according to some illustrative embodiments may be time-controlled cleaning processes that substantially conserve the capping layer, i.e., its thickness. The person skilled in the art understands that according optimized cleaning steps may further protect and conserve the gate electrode and in particular the high-k material. Therefore, semiconductor devices with well-defined properties and characteristics may be provided and production yield may be increased.

The present disclosure provides a semiconductor device having raised source and drain regions. The semiconductor device is formed by forming a gate electrode structure on a semiconductor substrate, forming a first spacer structure laterally to the gate electrode structure, forming a semiconductor layer over an exposed surface of the semiconductor substrate at both sides of the gate electrode structure such that a layer portion is formed which is beveled towards the gate electrode with regard to the exposed surface of the semiconductor substrate, and forming a second spacer structure over the first spacer structure, wherein the second spacer structure covers at least a portion of the beveled layer portion.

It is understood that processes as disclosed are perfectly compatible with the usage of stress transfer regions, especially as occurring in PFET devices for increasing carrier mobility. The person with ordinary skills in the art will appreciate that the aforementioned advantages result in an improved topography for better contact processes, lower contact resistances, lower serial resistances (series resistors), e.g., in CMOS structures, and increased device performances.

It is understood, that the order of steps can be changed in the above description. In the above description, numerous specific details are set forth such as, for example thicknesses, in order to provide a more thorough understanding of the present disclosure. Those skilled in the art will realize that the numerous specific details as provided may be equipment specific and may accordingly vary from one brand of equipment to another. It will be obvious, however, to one skilled in the art that the present disclosure may be practiced without these details. In other instances, well-known processes have not been described in detail in order to not unnecessarily obscure the present disclosure.

Although this invention has been described relative to specific insulating materials, conductive materials and deposited materials and etching of these materials, it is not limited to the specific materials but only to their specific characteristics, such as conformal and non-conformal, and capabilities, such as depositing and etching, other materials may be substituted as is well understood by those skilled in the arts after appreciating the present disclosure.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method for forming a semiconductor device having raised source and drain regions, the method comprising:
forming a gate electrode on a semiconductor substrate;
forming a first spacer structure disposed laterally to said gate electrode;
forming a semiconductor layer over an exposed surface of said semiconductor substrate at both sides of said gate electrode such that a layer portion is formed which is beveled towards said gate electrode with regard to said exposed surface of said semiconductor substrate; and
forming a second spacer structure over said first spacer structure, wherein said second spacer structure covers at least a portion of said beveled layer portion.

2. The method of claim 1, wherein forming said first spacer structure comprises depositing over said gate electrode a first insulating layer for forming a first spacer liner and a second insulating layer different from said first insulating layer, said second insulating layer having a thickness which is greater than the thickness of said first insulating layer.

3. The method of claim 2, wherein said first insulating layer comprises silicon nitride and said second insulating comprises silicon dioxide.

4. The method of claim 1, wherein forming said second spacer structure comprises depositing a third insulating layer for forming a second spacer liner and a fourth insulating layer on said third insulating layer and subsequently performing a reactive ion etch step.

5. The method of claim 4, wherein said third insulating layer comprises silicon dioxide and said fourth insulating layer comprises silicon nitride.

6. The method of claim 1, further comprising forming channel extension regions subsequent to forming said first spacer structure by implanting dopants of a first kind using said first spacer structure as a first masking pattern.

7. The method of claim 6, further comprising forming halo regions by implanting dopants of a second kind different from said first kind using said first masking pattern.

8. The method of claim 7, further comprising forming deep source regions and deep drain regions by using said second spacer structure as a second masking pattern during deep source/drain implantation.

9. The method of claim 8, further comprising removing a cap layer of said first spacer structure, said cap layer being disposed over said gate electrode, subsequent to forming said second spacer structure and prior to performing an annealing process for activating the implanted dopants.

10. The method of claim 1, further comprising performing a silicidation step for forming silicide regions in said semiconductor layer by using said second spacer structure as a masking pattern.

11. The method of claim 1, wherein forming said semiconductor layer close to said gate electrode comprises epitaxially growing undoped silicon on said semiconductor substrate.

12. A semiconductor device, comprising:
a semiconductor substrate having a transistor region on an exposed surface of said semiconductor substrate;
a gate electrode structure formed in said transistor region of said semiconductor substrate;
a first spacer structure formed in said transistor region disposed laterally to said gate electrode structure, wherein said first spacer structure covers a portion of said transistor region of said semiconductor substrate;
a raised source region and a raised drain region formed in an undoped semiconductor layer deposited on said semiconductor substrate in said transistor region at both sides of said gate electrode structure, wherein each of the raised source and drain regions has a layer portion which is beveled towards said gate electrode structure with regard to the exposed surface of said semiconductor substrate; and
a second spacer structure formed over said first spacer structure, said second spacer structure covering at least said beveled layer portions of said raised source and drain regions.

13. The semiconductor device of claim 12, wherein said first spacer structure comprises a first insulating layer forming a first spacer liner and a second insulating layer formed over said first insulating layer, said second insulating layer having a thickness which is greater than the thickness of said first insulating layer.

14. The semiconductor device of claim 13, wherein said first insulating layer comprises silicon nitride and said second insulating layer comprises silicon dioxide.

15. The semiconductor device of claim 12, wherein said second spacer structure comprises a third insulating layer forming a second spacer liner and a fourth insulating layer formed over said third insulating layer, said fourth insulating layer having a thickness which is greater than the thickness of said third insulating layer

16. The semiconductor device of claim 15, wherein said third insulating layer comprises silicon dioxide and said fourth insulating layer comprises silicon nitride.

17. The semiconductor device of claim 12, wherein said undoped semiconductor layer is formed of undoped silicon having a thickness between approximately 20-40 nm, said undoped silicon being deposited on said semiconductor substrate.

18. The semiconductor device of claim 12, wherein said semiconductor substrate comprises a silicon/germanium channel region under said gate electrode structure, having a content of silicon/germanium between approximately 19-30%.

19. The semiconductor device of claim 12, wherein said source and drain regions further comprise embedded stressor regions for imparting stress on a channel region which is located under said gate electrode structure.

20. The semiconductor device of claim 18, further comprising:
a second transistor region comprised of said semiconductor substrate;
a second gate electrode structure formed in said second transistor region of said semiconductor substrate;
a third spacer structure formed in said second transistor region laterally to said second gate electrode structure, said third spacer structure covering a portion of said second transistor region;
a second raised source region and a second raised drain region formed in an undoped semiconductor layer deposited on said semiconductor substrate in said second transistor region at both sides of said second gate electrode structure, wherein each of said second raised source and drain regions has a second layer portion which is beveled towards said second gate electrode structure with regard to an exposed surface of said semiconductor substrate;
a fourth spacer structure formed over said third spacer structure, said fourth spacer structure covering at least said beveled second layer portions of said second raised source and drain regions;
wherein said first and second raised source/drain regions are doped to form field effect transistors of N and P type.
